(19) United States
(12) Patent Application Publication
(10) Pub. No.: US 2009/0103751 A1
(43) Pub. Date: Apr. 23, 2009

(54) SOUND VOLUME LEVELER FOR SPEED SENSITIVE VOLUME

(76) Inventors: Stephen Gordon Lenk, Livonia, MI (US); J. William Whikehart, Milford, MI (US); Robert Kelly Cadena, Dearborn, MI (US)

Correspondence Address: VISTEON/BRINKS HOFER GILSON & LIONE, 524 South Main Street, Suite 200, Ann Arbor, MI, 48104, US

(21) Appl. No.: 11/876,287

(22) Filed: Oct. 22, 2007

(51) Int. Cl. H03G 3/00; H04B 1/00

(52) U.S. Cl. 381/104; 381/86

(57) ABSTRACT

A system and method for adjusting an output sound signal for an audio device includes a speed sensitive volume transfer unit, a dynamic processing unit and a sound volume update unit. The speed sensitive volume transfer unit is configured to output a volume gain signal based on a speed sensitive volume setting input, a volume gain input and an adjustment signal. The dynamic processing unit is in communication with the speed sensitive volume transfer unit and is configured to output a modified volume signal based upon the adjustment signal and the volume gain signal. The sound volume update unit is in communication with the dynamic processing unit and a raw sound signal. The sound volume update unit outputs a corrected sound signal based on the modified volume gain signal and the raw sound signal.

### BACKGROUND

1. Field of the Invention

The present invention generally relates to systems and methods for adjusting the volume of an audio system.

2. Description of the Known Technology

The volume of an audio system is adjusted by a user such that the user can hear audio signals emitted from the audio system. If the audio system is located in a room having very little ambient noise present, the user will generally adjust the volume of the audio system to a lower level. Conversely, if there are significant levels of ambient noise present in the room, the user will adjust the volume to a generally higher level. As long as the ambient noise remains at the same level, the user will not need to readjust the volume.

The ambient noise within an occupant compartment of an automobile varies greatly depending on wind noise and other noises, such as those generated by the automobile and by sources outside of the automobile. Because of these fluctuations in ambient noise, the volume of the audio system should be adjusted to correspond with the changes in ambient noise. One solution is to estimate the ambient noise based on a speed of the automobile. Generally, as the speed of the automobile increases, the ambient noise increases due to wind noise and noises generated by the automobile itself. Using this estimated ambient noise, the volume can be adjusted automatically to correspond with the estimated ambient noise.

One drawback to the above is that the speed of the automobile may vary greatly depending on the environment in which the automobile is operating. For example, when the automobile is traveling on an expressway, the speed of the automobile will generally vary slightly, although the ambient noise level may change as the highway becomes bumpy. When the automobile is traveling in an urban environment, the speed of the automobile may vary from slow speeds to high speeds. Since the volume of the automobile will be adjusted based upon the speed of the automobile, the volume of the audio system may be continuously changing. This may become annoying to the occupants of the automobile.

### BRIEF SUMMARY

In overcoming the drawbacks of the prior art, a system for adjusting the volume of an audio system, such as those found in an automobile, is described. The system includes a speed sensitive volume transfer unit, a dynamic processing unit and a sound volume update unit. The speed sensitive volume transfer unit is configured to output a volume gain signal based on a speed sensitive volume setting input, a volume gain input and an adjustment signal. The dynamic processing unit is in communication with the speed sensitive volume transfer unit and is configured to output a modified volume signal based upon the adjustment signal and the volume gain signal. Finally, the sound volume update unit is in communication with the dynamic processing unit and a raw sound signal. The sound volume update unit outputs a corrected sound signal based on the modified volume gain signal and the raw sound signal.

Further objects, features and advantages of this invention will become readily apparent to persons skilled in the art after a review of the following description, with reference to the drawings and claims that are appended to and form a part of this specification.

### BRIEF DESCRIPTION OF THE DRAWINGS

FIG. 1 is a perspective view of a occupant compartment of an automobile incorporating a system for adjusting the volume of an audio system embodying the principles of the present invention;

FIG. 2 is a block diagram of the system for adjusting the volume of an audio system utilizing a time constant filter;

FIG. 3 is a block diagram of the system for adjusting the volume of an audio system utilizing a dynamic processing unit;

FIG. 4 is a flow chart of a method for adjusting the output gain of the system;

FIG. 5 is a flow chart detailing another method for adjusting the output gain of the system; and

FIG. 6 is a flow chart of yet another method for adjusting the output gain of the system.

### DETAILED DESCRIPTION

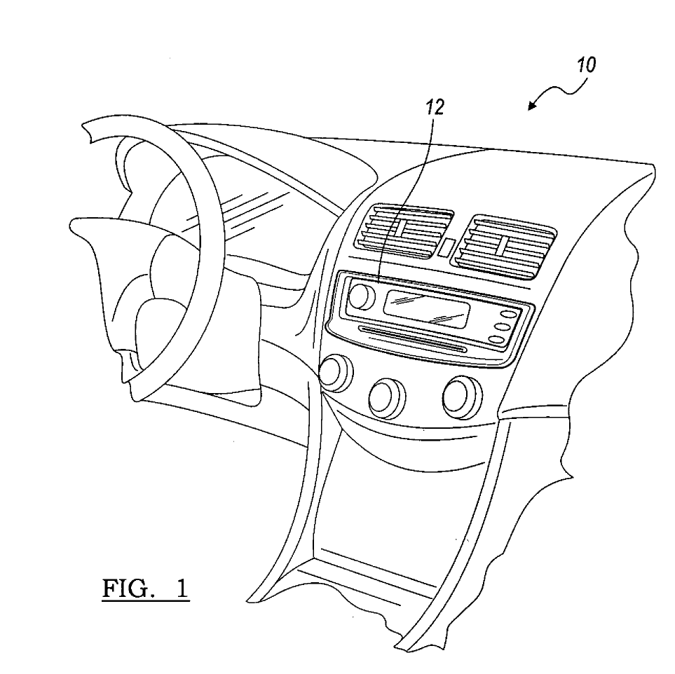

Referring to FIG. 1, an occupant compartment 10 of an automobile is shown. Located within the occupant compartment 10 is an audio system 12 capable of providing audio to an occupant of the occupant compartment 10. In this embodiment, the audio system 12 is only configured to output audio signals, but may be additionally configured to output video signals.

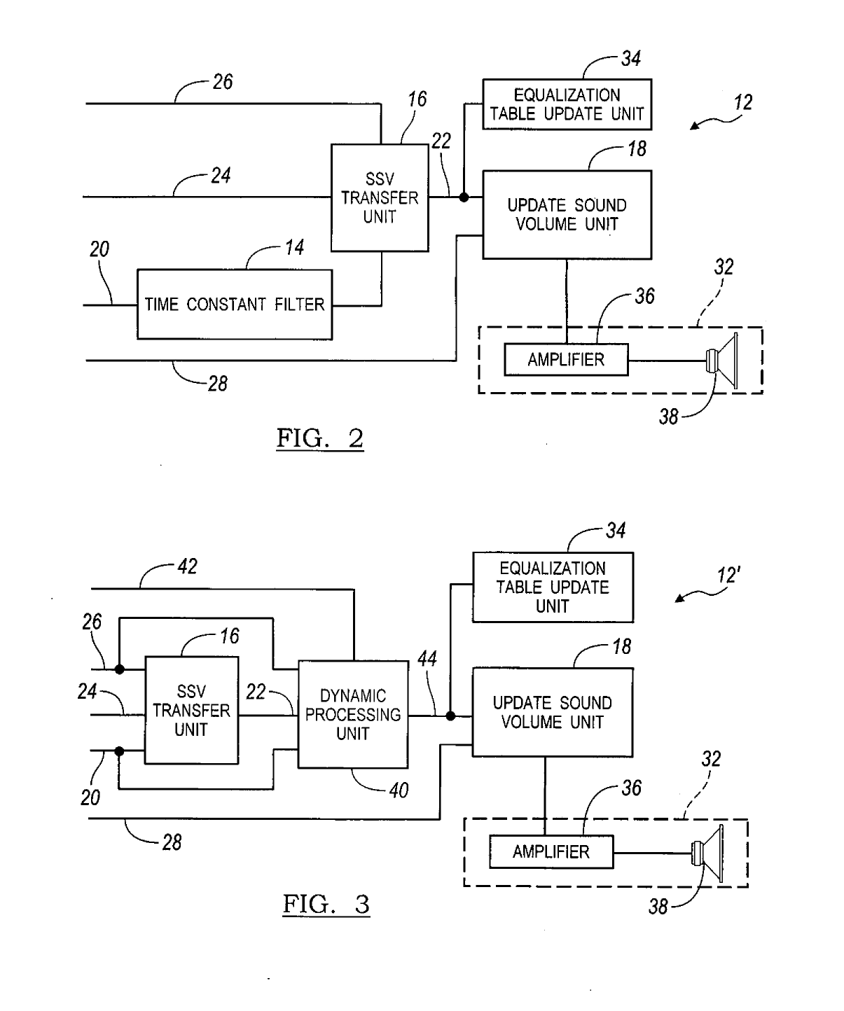

Referring to FIG. 2, a block diagram of the audio system 12 is shown. The block diagram includes a time constant filter 14, a speed sensitive volume (“SSV”) transfer unit 16 and an update sound volume unit 18. The SSV transfer unit 16 is in communication with both the time constant filter 14 and the sound volume update unit 18. The time constant filter 14 is a true filter that can be mathematically defined by a frequency-dependant linear transfer function.

An adjustment signal 20 is provided to the time constant filter 14. The adjustment signal 20 is a representation of the ambient noise within the occupant compartment 10 of the automobile and may be the output of an ambient noise sensor or may be a speed signal representing the speed of the automobile. As it is well known, the speed signal can be measured by the use of a wheel speed sensor configured to calculate the speed of the vehicle based on the rotation of at least one of the wheels of the automobile. It is known that ambient noise within the occupant compartment 10 of the automobile is approximately proportional to the speed in which the automobile is traveling.

If the adjustment signal 20 indicates significant amounts ambient noise within the occupant compartment 10 of the automobile, the volume will be adjusted upward. In like manner, if the adjustment signal 20 indicates that there are low levels of ambient noise within the occupant compartment 10 of the automobile, the volume will be adjusted generally downward. The time constant filter 14, after receiving the adjustment signal 20, adjusts the adjustment signal 20 over a period of time so as to minimize significant variations of the adjustment signal 20, and will reduce fluctuations in audio outputted by the audio system 22.

The SSV transfer unit 16 outputs a volume gain signal 22 based on the output of the time constant filter 14, a volume gain input 24 and a SSV setting input 26. The volume gain input 24 is a user defined input that is set by adjusting the volume of the entertainment system 12. For example, if the user of the entertainment system 12 adjusts the volume of the entertainment system 12 up or down, the volume gain input 24 will be accordingly adjusted up or down. The SSV setting input 26 is another user defined setting which indicates the maximum amount that the volume of the audio system 12 should be adjusted. For example, if the user of the audio system 12 only desires small variations in the volume of the audio system, the user can adjust the SSV setting input 26 to a lower value.

The volume gain signal 22 is essentially an adjusted volume gain input 24 which has been adjusted based on (1) the SSV input 26 set by the user and (2) the adjustment signal 20 as adjusted by the time constant filter 14. The volume gain signal 22 and a raw sound signal 28 are then provided to the update sound volume unit 18. The sound volume update unit 18 will output a corrected audio signal 30 to an audio output device 32. Additionally, an equalization table update unit 34 may be connected to the volume gain signal 22, so as to adjust the volume gain signal based upon user or previous selected equalization tables. The audio output device 32 generally includes an amplifier 36 connected to at least one speaker 38. The amplifier 36 will appropriately amplify the corrected audio signal 30 and output the amplified corrected audio signal 30 to the speaker 38.

Referring to FIG. 3, another embodiment of the audio system 12′ is shown. In this embodiment, the SSV transfer unit 16, the update sound volume unit 18, the equalization table update unit 34 and the audio output device 32 are similar to those shown and described in the previous embodiment. FIG. 2 differs from FIG. 1 in that the time constant filter 14 of FIG. 1 has been removed and a dynamic processing unit 40 has been added downstream from the SSV transfer unit 16. The dynamic processing unit 40 receives the volume gain signal 22 from the SSV transfer unit 16 and also receives the SSV input setting 26, which is provided in parallel to the SSV transfer unit, and the adjustment signal 20.

The dynamic processing unit 40 may optionally also be in communication with an ambient noise signal 42. Previously, it was stated that the adjustment signal 20 can be either the output of an ambient noise sensor or a speed signal. If an ambient noise signal 42 is in communication with the dynamic processing unit 10, the adjustment signal 20 will be based off the speed of the vehicle and not the ambient noise detected by an ambient noise sensor. This is because the ambient noise signal 42 is generated by an ambient noise sensor, relinquishing the need for the adjustment signal 20 being based on an additional ambient noise sensor.

The dynamic processing unit 40 uses the SSV setting input 26, the volume gain signal 22, the adjustment signal 20 and, optionally, the ambient noise signal 42 in calculating a modified volume gain signal 44. The modified volume gain signal 44 has adjusted the volume gain signal 22 so that any large variations caused by variations in the adjustment signal 20 have been minimized. The dynamic processing unit 40 may adjust the modified gain signal 44 over a period of time or may adjust the modified volume gain signal 44 after the adjustment signal 20 has remained steady over a period of time. Additionally, although the embodiment shown in FIG. 3 does not include a time constant filter 14, the time constant filter 14 may be utilized to further provide conditioning of the adjustment signal 20.

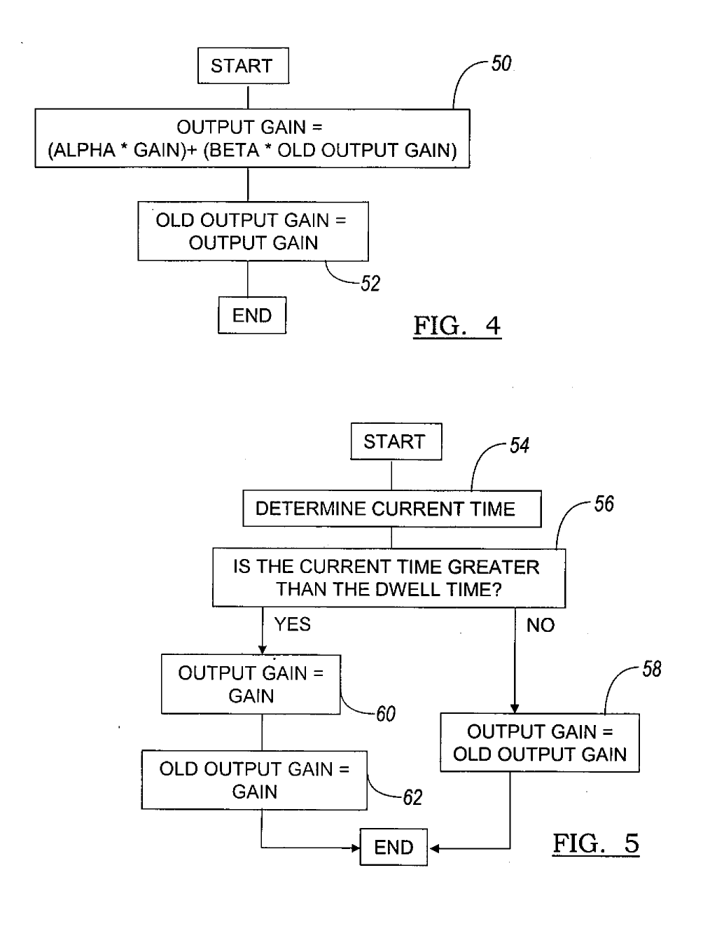

Referring to FIG. 4, a flow chart illustrating a method for adjusting the output gain is shown. The method shown in FIG. 4 first determines the value of an alpha variable and a beta variable. The alpha variable and beta variable may be generated by historical testing or by trial and error. Here, in step 50, the output gain equals the sum of alpha multiplied by the gain and beta multiplied by the old output gain. It should be understood that the term “gain” referred to in FIGS. 4-6 is the gain 22 referred to in the preceding paragraphs. In step 52, the old output gain is then set to equal the output gain. Thereafter, the method of FIG. 4 may be executed as necessary in order to properly adjust the output gain.

Referring to FIG. 5, another method for adjusting the output gain is shown. In step 54, a current time is determined. Thereafter, in step 56, a determination is made if the current time is greater than the dwell time. The dwell time is generally a preset time limit that represents a wait period. The wait period is a representation of the amount of time the system should delay before adjusting the output gain. For example, the system will only adjust the output gain when the dwell time has expired, which will have the effect of removing any sudden variations. Therefore, in step 58, if the current time is less than a dwell time, the output gain will equal the old output gain. Otherwise, as shown in step 60, the output gain will equal the gain. Thereafter, in step 62, the old output gain will be set to the gain, or may be gradually adjusted (skewed) to match the gain. Similar to the method shown in FIG. 4, this method can be executed as many times as necessary.

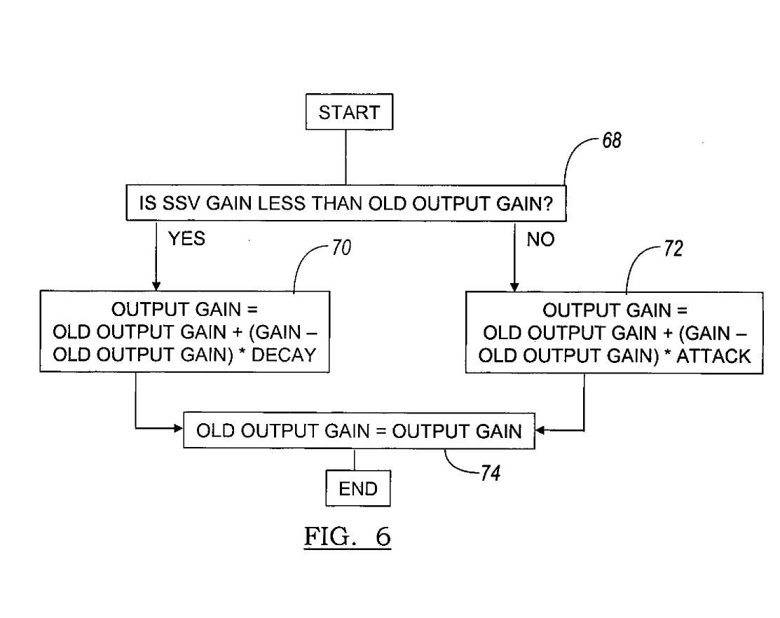

Referring to FIG. 6, another method for adjusting the output gain is shown. First, an attack and decay is determined. The attack and decay represent how aggressively the method will either increase or decrease the output gain. For example, if the attack and decay are set to be relatively large, the method will quickly adjust the output gain. Conversely, if the attack and decay are set to smaller amounts, the method will less quickly adjust the output gain.

In step 66, a determination is made if the SSV gain is less than the old output gain. If this is true, the old output gain will equal the old output gain multiplied by the decay value as shown in step 70. Otherwise, the output gain will equal the old output gain times an attack value as shown in step 72. Thereafter, in step 74 the old output gain is set to equal the output gain. Like the other methods, this method can be executed as many times as needed in order to effectively adjust the output gain.

As a person skilled in the art will readily appreciate, the above description is meant as an illustration of implementation of the principles this invention. This description is not intended to limit the scope or application of this invention in that the invention is susceptible to modification, variation and change, without departing from the spirit of this invention, as defined in the following claims.

1. A system for adjusting an output sound signal of an audio system, the system comprising:
a speed sensitive volume transfer unit, the speed sensitive volume transfer update unit configured to output a volume gain signal based on a speed sensitive volume setting input, a volume gain input and an adjustment signal;
a dynamic processing unit in communication with the speed sensitive volume transfer unit and the adjustment signal, the dynamic processing unit configured to output a modified volume gain signal based on the adjustment signal and the volume gain signal; and
a sound volume update unit in communication with the dynamic processing unit and a raw sound signal, the sound volume update unit configured to output a corrected sound signal output based on the modified volume gain signal and the raw sound signal.

2. The system of claim 1, wherein the adjustment signal is a speed signal, the speed signal being based on the speed of an automobile housing the entertainment system.

3. The system of claim 1, wherein the adjustment signal is an ambient noise signal.

4. The system of claim 1, wherein the dynamic processing unit is configured to adjust the modified volume gain signal after the adjustment signal has remained steady over a period of time.

5. The system of claim 1, wherein the dynamic processing unit is configured to adjust the modified volume gain signal at a specific rate.

6. The system of claim 1, further comprising a filter in communication with the speed sensitive volume transfer unit, the filter configured to adjust an adjustment signal over a period of time.

7. A system for adjusting the an output sound signal for an audio system, the system comprising:
a filter, the filter configured to adjust an adjustment signal over a period of time;
a speed sensitive volume transfer unit in communication with the filter, the speed sensitive volume update unit configured to output a volume gain signal based on a speed sensitive volume setting input, a volume gain input and the adjustment signal; and
a sound volume update unit in communication with the speed sensitive volume transfer unit and a raw sound signal, the sound volume update unit configured to output a corrected sound signal output based on the volume gain input and the raw sound signal.

8. The system of claim 7, wherein the adjustment signal is a speed signal, the speed signal being based on the speed of an automobile housing the entertainment system.

9. The system of claim 7, wherein the adjustment signal is an ambient noise signal.

10. The system of claim 7, wherein the filter is configured to adjust the adjustment signal after the adjustment signal has remained steady over a period of time.

11. The system of claim 7, wherein the filter unit is configured to adjust the adjustment signal over a period of time.

12. A method for adjusting an output sound signal of an audio system, the method comprising the steps of:
receiving an adjustment signal;
modifying the adjustment signal over a period of time to create a modified adjustment signal; and
adjusting the output sound signal based upon the modified adjustment signal.

13. The method of claim 12, wherein the adjustment signal is a speed signal, the speed signal being based on the speed of an automobile in which the audio system is located.

14. The method of claim 12, wherein the adjustment signal is an ambient noise signal.

15. The method of claim 12, further comprising the step of adjusting the sound signal based upon the adjustment signal and a speed sensitive volume setting.

16. The method of claim 12, further comprising the step of adjusting the sound signal after the adjustment signal has remained steady over a certain period of time.

17. The method of claim 12, further comprising the step of adjusting the sound signal over a period of time on the adjustment signal.
